(19) United States
(12) Patent Application Publication
(10) Pub. No.: US 2009/0121301 A1
(43) Pub. Date: May 14, 2009

(54) IMAGE CAPTURE MODULE

(75) Inventor: JEN-TSORNG CHANG, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/202,537

(22) Filed: Sep. 2, 2008

(30) Foreign Application Priority Data
Nov. 9, 2007 (CN) 200710202439.2

(51) Int. Cl. H01L 31/00

(52) U.S. Cl. 257/432; 257/E31.001

(57) ABSTRACT

An image capture module includes an image sensor and a photochromic glass plate. The image sensor includes a photosensitive area. The photochromic glass plate is positioned in front of the photosensitive area, adjusting light transmittance therethrough according to current ambient light conditions, thereby adjusting exposure value of the image sensor. In addition to the image sensor and the photochromic glass plate, the image capture module may further include a lens unit and a packaging substrate. The substrate defines a cavity therein, in which the image sensor is disposed. The photochromic glass plate seals the cavity. The lens unit is disposed on the photochromic glass plate. During image capture, light enters and is transmitted through the lens unit and the photochromic glass plate, forming an image on the photosensitive area of the image sensor. The image sensor converts the visual image into digital data.

### BACKGROUND

1. Technical Field

The present invention relates to imaging technology and, particularly, to an image capture module with auto-exposure function.

2. Description of the Related Art

Generally, exposure value is an important factor in the quality of captured images, as determined by exposure time (shutter speed) and aperture value. Most current cameras provide an automatic exposure function, in which the camera automatically determines the appropriate exposure time and aperture value for current ambient light conditions. This determination is typically accomplished by utilizing algorithms executed in a processor(s) of the camera, although this can increase the workload on the processor(s) and power consumption.

Therefore, what is desired is an image capture module providing auto-exposure function that overcomes the described limitations.

### SUMMARY

In accordance with an embodiment, an image capture module is disclosed. The image capture module includes an image sensor and a photochromic glass plate. The image sensor includes a photosensitive area. The photochromic glass plate is positioned in front of the photosensitive area, and is capable of adjusting light transmittance therethrough according to current ambient light conditions, thereby adjusting the exposure value of the image sensor. In addition to the image sensor and the photochromic glass plate, the image capture module may further include a lens unit and a packaging substrate. The substrate defines a cavity therein, in which the image sensor is disposed. The photochromic glass plate seals the cavity. The lens unit is disposed on the photochromic glass plate. During image capture, light enters and is transmitted through the lens unit and the photochromic glass plate, forming an image on the photosensitive area of the image sensor. The image sensor converts the visual image to digital data.

### BRIEF DESCRIPTION OF THE DRAWINGS

Many aspects of the present image capture module can be better understood with reference to the attached drawings. The components in the drawings are not necessarily drawn to scale, the emphasis instead being placed upon clearly illustrating the principles of the present image capture module. Moreover, in the drawings, like reference numerals designate corresponding parts throughout the several views.

FIG. 1 is a schematic cross-section of an image capture module according to an exemplary embodiment.

FIG. 2 is a schematic cross-section of an image capture module according to another exemplary embodiment.

### DETAILED DESCRIPTION

Embodiments of the present image capture module will be now described in detail with reference to the drawings.

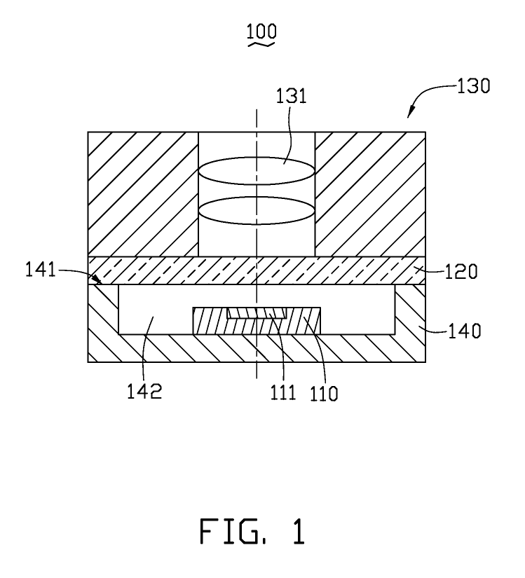

Referring to FIG. 1, an image capture module 100 in accordance with an embodiment is illustrated. The image capture module 100 includes an image sensor 110 and a photochromic glass plate 120. The image sensor 110 includes a photosensitive area 111. The photochromic glass plate 120 is positioned in front of the photosensitive area 111, and is capable of adjusting light transmittance therethrough according to current ambient light conditions, thereby adjusting exposure value of the image sensor 110. Particularly, in addition to the image sensor 110 and the photochromic glass plate 120, the image capture module 100 may further include a lens unit 130 and a packaging substrate 140. The substrate 140 defines a cavity 142 therein, in which the image sensor 110 is disposed and the photochromic glass plate 120 seals the cavity 142. The lens unit 130 is disposed on the photochromic glass plate 120. During image capture, light enters and is transmitted through the lens unit 130 and the photochromic glass plate 120, forming an image on the photosensitive area 111 of the image sensor 110. The image sensor 110 converts the visual image into digital data.

The image sensor 110 can be a charged coupled device (CCD), or a complementary metal-oxide-semiconductor (CMOS). The image sensor 110 may be mechanically and electrically packaged on the substrate 140 by various package processes, such as chip-scale package (CSP), wafer-level chip-scale, ceramic leaded chip carrier (CLCC), plastic leaded chip carrier (PLCC), thermal compression bonding, or flip chip packaging.

While photochromic glass plate 120 is positioned above the image sensor 110 and the lens unit 130 positioned thereon, it should be noted that the embodiment is not limited thereto. For example, in alternative embodiments, the photochromic glass plate 120 can be placed at the object side of the lens unit 130, accordingly using another cover glass to seal the image sensor 110.

The photochromic glass plate 120 is glass doped with photosensitizer. The glass can be aluminum borosilicate, borate, or phosphate glass. The photosensitizer can be silver halide such as AgCl, AgBr or AgI. The grayness of this photochromic glass plate 120 typically varies depending on the intensity of light incident thereon, increasing with intensity of the incident light, with corresponding increase in absorption of light, resulting in reduced light transmittance of the photochromic glass plate 120. As a result, the aperture value is adjusted to a low value. Conversely, when ambient light is weak, the photochromic glass plate 120 exhibits reduced grayness, with corresponding decrease in absorption of light and higher light transmittance of the photochromic glass plate 120. As a result, the aperture value is adjusted to a high value.

In principle, photosensitizer such as AgCl, AgBr or AgI doped in glass will be broken down by ambient light equaling or exceeding a predetermined intensity, into sliver particles and halogen molecules, such as Cl₂, Br₂ or I₂. This photochemical reaction is expressed by the following:

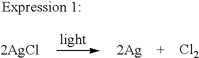

The small particles of silver will diffuse light transmitted thereby, decreasing light transmittance of the photochromic glass plate 120. When the intensity of the ambient light drops below the predetermined intensity, reverse photochemical reaction takes place. This reverse photochemical reaction can be expressed by the following:

Expression 2

2Ag+Cl₂→2AgCl

When the reverse photochemical reaction occurs, the sliver particles are recombined with the halogen molecules, and the photochromic glass plate 120 is restored to its original transparent status.

The photochromic glass plate 120 can be fabricated by doping a small amount of silver halide AgCl (or AgBr, or AgI) into aluminum borosilicate glass, borate glass, or phosphate glass as potosensitizer; doping a minor amount of copper ion and cadmium ion as catalyzer; melting the compound into a glass plate at a desired temperature to form silver halide particles therein. In the illustrated embodiment, the diameter of the silver halide particles is in a range of 500 to 1000 nanometers (nm).

In addition, the thickness and dopant concentration of the photochromic glass plate 120 can be optimized so that when the photosensitizer is completely broken down into silver particles and halogen molecules under intensive ambient light, light transmittance of the photochromic glass plate 120 falls below 30%, and conversely when the photosensitizer experiences no photochemical decomposition, light transmittance of the photochromic glass plate 120 exceeds 90%, providing a favorably wide adjustment range of exposure value.

The lens unit 130 may include one or more lenses 131 optically coupled with the image sensor 110, and is configured for directing ambient light to the photochromic glass plate 120.

The substrate 140 can be polyimide, ceramic, or glass fiber. The substrate 140 has a supporting surface 141, on which the photochromic glass plate 120 and lens unit 130 are supported.

The image capture module 100 adjusts exposure value by employing photochromic glass plate 120 in the light path. That is, the photochromic glass plate 120 replaces aperture-based controlling devices of conventional camera modules, further satisfying requirements for smaller camera units.

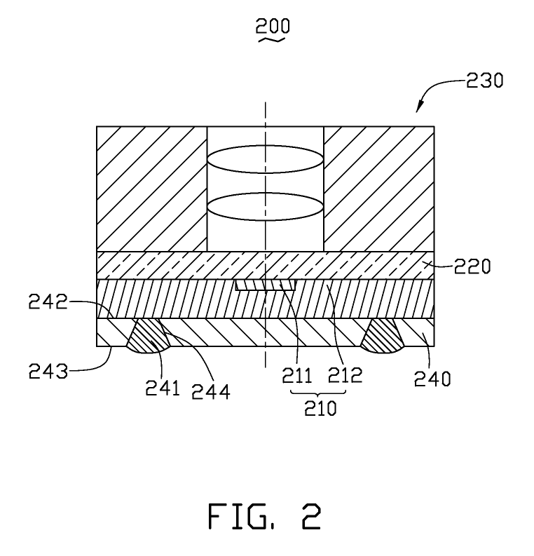

FIG. 2 illustrates an image capture module 200, in accordance with a second exemplary embodiment, differing from image capture module 100 of the first embodiment only in the substrate 240. The image capture module 200 utilizes a wafer-level package to integrate the image sensor 210 with the photochromic glass plate 220.

The substrate 240 has a supporting surface 242 supporting the image sensor 210 and a bottom surface 243 opposite to the supporting surface 242. The substrate 240 includes a number of holes 244 through the supporting surface 242 and the bottom surface 243. A number of welding pads 241 electrically connecting to an outer circuit board are respectively provided in the corresponding holes 244. The welding pads 241 can be ball grid array (BGA), leadless chip carrier (LCC), or lead frame package type.

It will be understood that the above particular embodiments and methods are shown and described by way of illustration only. The principles and the features of the present invention may be employed in various and numerous embodiments thereof without departing from the scope of the invention as claimed. The above-described embodiments illustrate the scope of the invention but do not restrict the scope of the invention.

What is claimed is:

1. An image capture module comprising:
an image sensor including a photosensitive area;
a photochromic glass plate positioned in front of the photosensitive area of the image sensor, adjusting light transmittance therethrough according to current ambient light conditions.

2. The image capture module as claimed in claim 1, wherein the photochromic glass plate is glass doped with photosensitizer.

3. The image capture module as claimed in claim 2, wherein the potosensitizer is silver halide.

4. The image capture module as claimed in claim 2, wherein the glass is aluminum borosilicate glass, borate glass or phosphate glass.

5. The image capture module as claimed in claim 3, wherein the silver halide is AgCl, AgBr or AgI.

6. An image capture module comprising:
an image sensor including a photosensitive area;
a lens module optically coupled with the image sensor;
a photochromic glass plate positioned in front of the photosensitive area of the image sensor, adjusting light transmittance therethrough according to current ambient light conditions.

7. The image capture module as claimed in claim 6, wherein the photochromic glass plate is glass doped with photosensitizer.

8. The image capture module as claimed in claim 7, wherein the potosensitizer is silver halide.

9. The image capture module as claimed in claim 7, wherein the glass is aluminum borosilicate glass, borate glass, or phosphate glass.

10. The image capture module as claimed in claim 8, wherein the silver halide is AgCl, AgBr or AgI.

11. An image capture module comprising:
an image sensor including a photosensitive area;
a lens module optically coupled with the image sensor;
a photochromic glass plate positioned in front of the photosensitive area of the image sensor, adjusting light transmittance therethrough according to current ambient light conditions;
a substrate comprising a supporting surface and a bottom surface opposite to the supporting surface, and the lens unit, the photochromic glass plate, and the image sensor being supported on the supporting surface.

12. The image capture module as claimed in claim 11, wherein the supporting surface of the substrate defines a cavity receiving the image sensor.

13. The image capture module as claimed in claim 11, wherein the substrate includes a plurality of holes through the supporting surface and the bottom surface, and a plurality of welding pads electrically connecting to an outer circuit board respectively provided in the corresponding holes.

14. The image capture module as claimed in claim 13, wherein the plurality of welding pads are ball grid array (BGA), leadless chip carrier (LCC), or lead frame package type.

15. The image capture module as claimed in claim 1, wherein the photochromic glass plate is sandwiched between the lens unit and the image sensor.

16. The image capture module as claimed in claim 11, wherein the photochromic glass plate is placed at the object side of the lens unit.

17. The image capture module as claimed in claim 11, wherein the photochromic glass plate is glass doped with photosensitizer.

18. The image capture module as claimed in claim 17, wherein the potosensitizer is silver halide.

19. The image capture module as claimed in claim 17, wherein the glass is aluminum borosilicate glass, borate glass, or phosphate glass.

20. The image capture module as claimed in claim 18, wherein the silver halide is AgCl, AgBr or AgI.
